(19) United States
(12) Patent Application Publication
(10) Pub. No.: US 2025/0095933 A1
(43) Pub. Date: Mar. 20, 2025

(54) PIEZOELECTRIC SWITCH WITH ADJUSTABLE CONTACT FORCE AND DISPLACEMENT

(71) Applicant: Georgia Tech Research Corporation, Atlanta, GA (US)

(72) Inventors: Luke Graber, Atlanta, GA (US); Zhiyang Jin, Atlanta, GA (US)

(21) Appl. No.: 18/727,837

(22) PCT Filed: Jan. 11, 2023
(86) PCT No.: PCT/US2023/060477

§ 371 Date: Jul. 10, 2024

Related U.S. Application Data
(60) Provisional application No. 63/298,525, filed on Jan. 11, 2022.

(51) Int. Cl. H01H 21/36; H01H 21/22

(52) U.S. Cl. CPC H01H 21/36; H01H 21/22

(57) ABSTRACT

A system for an electromechanical transfer or disconnect switch wherein the system can comprise one or more contacts. a mechanical lever, and an actuator. The mechanical lever can comprise a first end, which can comprise a pivot and one or more holes disposed proximal to the pivot configured to provide a variable mechanical gain, and a second end coupled to at least a first contact in the one or more contacts. The actuator may be a piezoelectric or magnetostrictive actuator and can comprise a first end and a second end wherein the second end can be couplable to the one or more holes on mechanical lever, such that actuation of the actuator may cause a displacement of the at least a first contact relative to at least a second contact in the one or more contacts. The second contact may be movable or stationary.

### CROSS-REFERENCE TO RELATED APPLICATIONS

This application claims the benefit of U.S. Provisional Application Ser. No. 63/298,525, filed on 11 Jan. 2022, which is incorporated herein by reference in its entirety as if fully set forth below.

### GOVERNMENT LICENSING RIGHTS

This invention was made with government support under Agreement No. DE-AR0001113, awarded by the Department of Energy. The government has certain rights in the invention.

### FIELD OF INVENTION

The present disclosure relates, generally, to electric power systems. More specifically, it relates to mechanical switches (e.g., transfer or disconnect switches) in a hybrid circuit breaker.

### BACKGROUND

A disconnect switch is an electrical component capable of transferring loads between multiple sources. In the past, fast disconnect switches have been developed from Thomson coils, power electronics, propellant-based systems, or coupled electromechanical and hydraulic systems. However, each of the foregoing is flawed. Thomson coils require high current pulses, power electronics switches have significant conduction losses, propellant based systems cannot be automatically reset, and coupled electromechanical and hydraulic systems can be complex and slow.

For conventional disconnect switch applications where non-current-carrying electrical conductors are physically moved to achieve separation from each other, and thus creating electrical isolation, coupled mechanical systems are used to separate the contacts enough so that the voltage withstand of the contact gap is sufficient for the application. This contact separation is conventionally achieved by an indirect application of force through a series of levers, a direct application of force with the contacts enclosed in a vacuum or pressurized gas medium (called the switching chamber), or a combination of the two methods. One of the drawbacks of these methods is the fact that they are too slow and cumbersome in achieving the necessary voltage withstand capability for ultrafast medium voltage (1 kV-69 kV) switching applications. Such types of disconnect switches are not suitable for the hybrid power electronics and mechanical disconnect switch that are currently being developed around the world.

To handle high magnitude fault currents in a system, large, slow circuit breakers are typically used. However, the need to deal with these fault currents can be replaced with a need to operate as fast as possible to provide sufficient flexibility and re-configurability of the system. Accordingly, what is needed is an ultrafast disconnect/transfer switch that is simple, compact, does not need high energy to operate (relative to the Thomson coil designs), ultralow loss (relative to the power electronic solution), clean, and capable of being automatically reset (as compared to the propellant based systems), thus providing more effective control over use and control of power.

### SUMMARY

An exemplary embodiment of the present disclosure provides a system for an electromechanical transfer or disconnect switch wherein the system can comprise one or more contacts, a mechanical lever, and an actuator. The mechanical lever can comprise a first end, which can comprise a pivot and one or more holes disposed proximal to the pivot configured to provide a variable mechanical gain, and a second end coupled to at least a first contact in the one or more contacts. The actuator may be a piezoelectric or magnetostrictive actuator and can comprise a first end and a second end wherein the second end can be couplable to the one or more holes on mechanical lever, such that actuation of the actuator may cause a displacement of the at least a first contact relative to at least a second contact in the one or more contacts. The second contact may be movable or stationary.

In any of the embodiments disclosed herein, the one or more contacts can comprise one or more stationary contacts and one or more movable contacts. The one or more movable contacts may be coupled to one or more contact guides configured to be disposed a variable distance from the one or more stationary contacts.

In any of the embodiments disclosed herein, the system can further comprise a counter block configured to adjust the variable distance between the one or more stationary contacts and the one or more movable contacts, wherein the first end of the actuator may be coupled to the counter block.

In any of the embodiments disclosed herein, the piezoelectric actuator can be configured to bias between an extended state and a retracted state upon reception of an activation signal. The piezoelectric actuator can be configured to, upon receiving the activation signal, bias to the extended state and can be configured to displace the second end of the mechanical lever thus reducing the variable distance between the one or more stationary contacts and the one or more movable contacts.

In any of the embodiments disclosed herein, the piezoelectric actuator can be configured to, upon receiving the activation signal, bias to the contracted state and can be configured to displace the second end of the mechanical lever thus increasing the variable distance between the one or more stationary contacts and the one or more movable contacts.

In any of the embodiments disclosed herein, the system can be configured such that moving the second end of the actuator between the one or more holes of the mechanical lever adjusts the variable mechanical gain of the mechanical lever. The variable mechanical gain of the mechanical lever can increase when the second end of the actuator is coupled to the one or more holes of the mechanical lever proximal to the pivot of the mechanical lever. The variable mechanical gain of the mechanical lever can decrease when the second end of the actuator is coupled to the one or more holes of the mechanical lever distal to the pivot of the mechanical lever.

In any of the embodiments disclosed herein, the system can further comprise a stepper motor that can be configured to displace the counter block and therein adjust the variable distance between the one or more stationary contacts and the one or more moveable contacts. The stepper motor can be further configured to be coupled to the counter block via a lead ball screw.

Another embodiment of the present disclosure provides an electromechanical transfer or disconnect switch wherein the switch can comprise one or more contacts, a mechanical lever, and an actuator. The mechanical lever can comprise a first end, which can comprise a pivot and one or more holes disposed proximal to the pivot configured to provide a variable mechanical gain, and a second end coupled to at least a first contact in the one or more contacts. The actuator may be a piezoelectric or magnetostrictive actuator and can comprise a first end and a second end wherein the second end can be couplable to the one or more holes on mechanical lever, such that actuation of the actuator may cause a displacement of the at least a first contact relative to at least a second contact in the one or more contacts. The second contact may be movable or stationary.

In any of the embodiments disclosed herein, the one or more contacts can comprise one or more stationary contacts and one or more movable contacts. The one or more movable contacts may be coupled to one or more contact guides configured to be disposed a variable distance from the one or more stationary contacts.

In any of the embodiments disclosed herein, the switch can further comprise a counter block configured to adjust the variable distance between the one or more stationary contacts and the one or more movable contacts, wherein the first end of the actuator may be coupled to the counter block.

In any of the embodiments disclosed herein, the piezoelectric actuator can be configured to bias between an extended state and a retracted state upon reception of an activation signal. The piezoelectric actuator can be configured to, upon receiving the activation signal, bias to the extended state and can be configured to displace the second end of the mechanical lever thus reducing the variable distance between the one or more stationary contacts and the one or more movable contacts.

In any of the embodiments disclosed herein, the piezoelectric actuator can be configured to, upon receiving the activation signal, bias to the contracted state and can be configured to displace the second end of the mechanical lever thus increasing the variable distance between the one or more stationary contacts and the one or more movable contacts.

In any of the embodiments disclosed herein, the switch can be configured such that moving the second end of the actuator between the one or more holes of the mechanical lever adjusts the variable mechanical gain of the mechanical lever. The variable mechanical gain of the mechanical lever can increase when the second end of the actuator is coupled to the one or more holes of the mechanical lever proximal to the pivot of the mechanical lever. The variable mechanical gain of the mechanical lever can decrease when the second end of the actuator is coupled to the one or more holes of the mechanical lever distal to the pivot of the mechanical lever.

In any of the embodiments disclosed herein, the switch can further comprise a stepper motor that can be configured to displace the counter block and therein adjust the variable distance between the one or more stationary contacts and the one or more moveable contacts. The stepper motor can be further configured to be coupled to the counter block via a lead ball screw.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF DRAWINGS

The above and further aspects of this invention are further discussed with reference to the following description in conjunction with the accompanying drawings, in which like numerals indicate like structural elements and features in various figures. The drawings are not necessarily to scale, emphasis instead being placed upon illustrating principles of the invention. The figures depict one or more implementations of the inventive devices, by way of example only, not by way of limitation.

FIG. 1 is an illustration of the elements of an exemplary piezoelectric switch. The elements can include a piezoelectric actuator, mechanical lever, one or more stationary and movable contacts, contact guides, and a counter block in accordance with an exemplary embodiment of the present disclosure.

FIG. 2 is an illustration of a first configuration of an exemplary piezoelectric switch in accordance with an exemplary embodiment of the present disclosure.

FIG. 3 is an illustration of a second configuration of an exemplary piezoelectric switch in accordance with an exemplary embodiment of the present disclosure.

FIG. 4. is an illustration of an alternate arrangement of a second configuration of an exemplary piezoelectric switch in accordance with an exemplary embodiment of the present disclosure.

FIG. 5 is an illustration of an exemplary piezoelectric switch with a stepper motor and lead ball screw in accordance with an exemplary embodiment of the present disclosure.

### DETAILED DESCRIPTION

The following detailed description should be read with reference to the drawings, in which like elements in different drawings are identically numbered. This description enables one skilled in the art to make and use the invention, and describes several embodiments, adaptations, variations, alternatives and uses of the invention, including what is presently believed to be the best mode of carrying out the invention. Any one or more of the teachings, expressions, versions, examples, etc. described herein may be combined with any one or more of the other teachings, expressions, versions, examples, etc. that are described herein. The following-described teachings, expressions, versions, examples, etc. should therefore not be viewed in isolation relative to each other. Various suitable ways in which the teachings herein may be combined will be readily apparent to those skilled in the pertinent art in view of the teachings herein. Such modifications and variations are intended to be included within the scope of the claims.

It must also be noted that, as used in the specification and the appended claims, the singular forms “a,” “an” and “the” include plural references unless the context clearly dictates otherwise. For example, reference to a component is intended also to include composition of a plurality of components. References to a composition containing “a” constituent is intended to include other constituents in addition to the one named.

Also, in describing the exemplary embodiments, terminology will be resorted to for the sake of clarity. It is intended that each term contemplates its broadest meaning as understood by those skilled in the art and includes all technical equivalents which operate in a similar manner to accomplish a similar purpose.

By “comprising” or “containing” or “including” is meant that at least the named compound, element, particle, or method step is present in the composition or article or method, but does not exclude the presence of other compounds, materials, particles, method steps, even if other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The materials described as making up the various elements of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

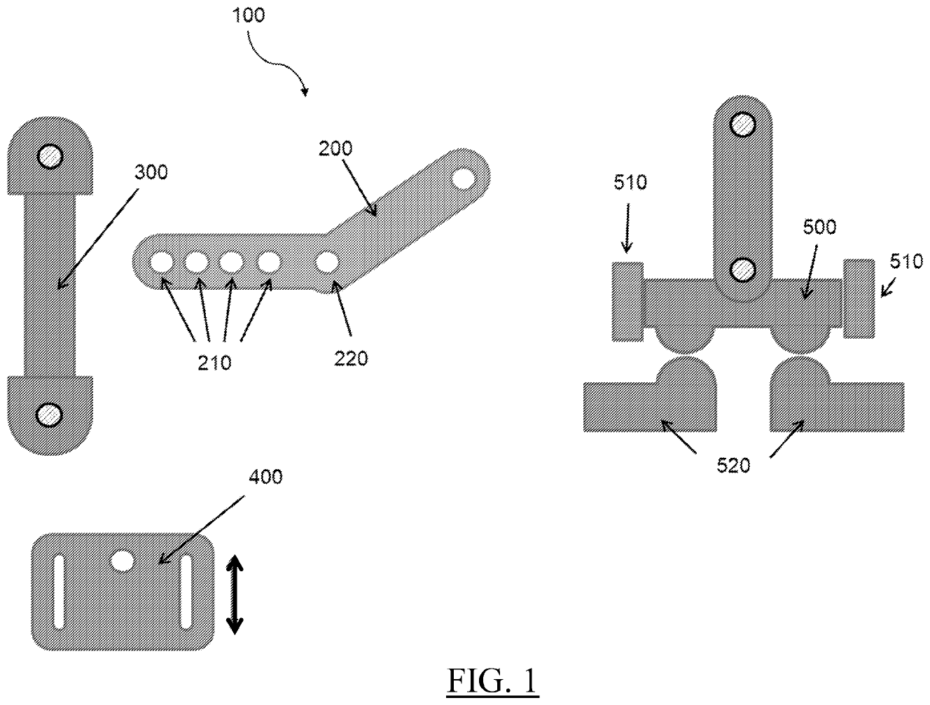

FIG. 1 is an illustration of the elements of an exemplary piezoelectric switch 100 in accordance with the present disclosure. As shown in FIG. 1, the piezoelectric switch 100 can include components such as a mechanical lever 200, piezoelectric actuator 300, counter block 400, and one or more contacts. In some embodiments, the one or more contacts can include one or more moving contacts 500, which may be held in place by contact guards 510, and one or more stationary contacts 520. In some embodiments, the contact guards 510 may be one piece of a material, with a hole in the middle to fit in the movable contacts. As one skilled in the art will appreciate, contact guides are dielectric materials, which can include polymers with a low friction coefficient and high wear resistance. Examples of contact guide materials can include but not be limited to fluoropolymers, such as polytetrafluoroethylene (PTFE), polyamides, such as Nylon 6,6, and the like. As one skilled in the art will also appreciate, the type of contact guide used may depend on factors including but not limited to environmental operational conditions, contact displacement, voltage or current ratings of the disconnect switch, and the like.

The mechanical lever 200 can include a one or more holes 210 and a pivot 220. The design of the piezoelectric switch 100 leveraging both the mechanical lever 200 in conjunction with the piezoelectric actuator 300 is advantageous as it can allow the piezoelectric switch 100 to realize various gains from the output force of piezoelectric actuator 300, which therein can allow the piezoelectric switch 100 to adjust contact force between the one or more contacts without altering contact displacement and adjust contact displacement without altering the contact force between the one or more contacts. As one skilled in the art will appreciate, a transfer switch that can increase contact force without sacrificing contact displacement contributes to lower electrical losses and thus higher operational efficiency of said transfer switch.

In some embodiments, various gains may be realized by increasing or decreasing the mechanical gain of the mechanical lever 200. The mechanical gain may be increased or decreased within the piezoelectric switch 100 by coupling the piezoelectric actuator 300 to the one or more holes 210 of the mechanical lever 200. As one skilled in the art will appreciate, by selecting one of the one or more hole 200 on the mechanical arm 200 disposed proximal to the pivot 220 of the mechanical lever 200, the piezoelectric switch 100 can realize a higher mechanical gain based on the output force of the piezoelectric actuator 300. Conversely, by selected one of the one or more holes 210 of the mechanical lever 200 disposed distal to the pivot 220 of the mechanical lever 200, the piezoelectric switch 100 may realize a lower mechanical gain based on the output force of the piezoelectric actuator 300. In some embodiments, the one or more holes 210 may include bushings such as sleeve bearings, sinister bearings, and the like at. As one skilled in the art will also appreciate, the utilization of bushings within embodiments of the piezoelectric switch 100, is advantageous in reduce mechanical stress that may be attributed to the friction of connected parts.

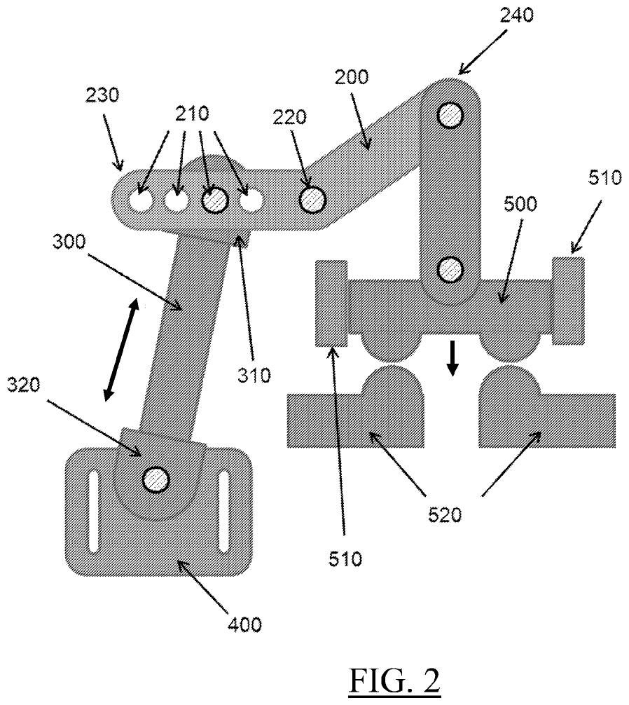

FIG. 2 is an illustration of a first configuration of an exemplary piezoelectric switch in accordance with an exemplary embodiment of the present disclosure. In some embodiments, the first configuration of the piezoelectric switch 100 may be a normally open configuration. As one skilled in the art will appreciate, normally open configuration for electrical devices and switches are an electrical state where current is not allowed to flow through until the electrical device or switch is activated to complete or close the circuit. For example, the piezoelectric actuator 300 may be configured to bias between operating in an extended state and a retracted state. In the normally open configuration, the piezoelectric actuator 300 may initially operate in a retracted state as shown in FIG. 2. Upon receiving an activation signal, the piezoelectric actuator 300 can bias to an extended state, which can exert an output force to the mechanical lever 200 and therein exert a mechanical gain on the one or more movable contacts 500 to reduce the distance with the one or more stationary contacts 520 thus closing the piezoelectric switch 100. As one skilled in the art will appreciate, the activation signal to bias the piezoelectric actuator 300 may include an applied voltage across the terminals. The first end of the piezoelectric actuator 310, as shown in FIG. 2, can be coupled to the one or more holes 210 of the mechanical lever 200 to realize various gains. The second end of the piezoelectric actuator 320, also shown in FIG. 2, may be coupled to the counter block 400 to realize various offsets between the one or more contacts. Once the gain has been selected, the counter block 400 may be used to set a zero point for the piezoelectric switch 100. The zero point set by the counter block 400 in the normally open configuration, for example, may be a position that keeps the distance of the one or more contacts constant. In some embodiments, the counter block 400 can include one or more fasten bolts wherein the position of the one or more fasten bolts can be adjusted to therein adjust the position of the counter block 400.

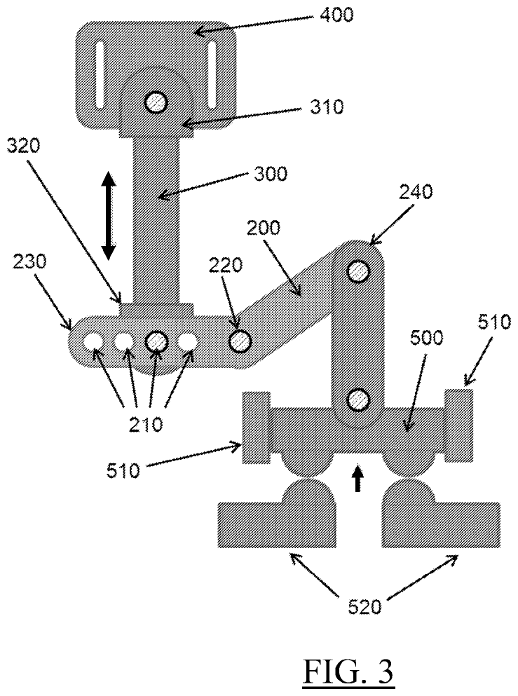

FIG. 3 is an illustration of a second configuration of an exemplary piezoelectric switch in accordance with an exemplary embodiment of the present disclosure. In some embodiments, the second configuration of the piezoelectric switch 100 may include a normally closed configuration. As one skilled in the art will appreciate, a normally closed configuration for electrical devices and switches are an electrical state where current is allowed to flow through until the electrical device or switch is activated to until the electrical device or switch is activated to break or open the circuit. For example, the piezoelectric actuator 300 while in the normally closed configuration may initially operate in an extended state as shown in FIG. 3. Upon receiving an activation signal, the piezoelectric actuator 300 can bias to the retracted state, which can exert an output force to the mechanical lever 200 and therein exert a mechanical gain on the one or more movable contacts 500 to increase the distance from the one or more stationary contacts 520 thus placing the piezoelectric switch 100 in a normally open configuration. As one skilled in the art will appreciate, the activation signal to bias the piezoelectric actuator 300 may include an applied voltage across the terminals. As mentioned previously, the counter block may be used to set a zero point for the piezoelectric switch 100. In the normally closed configuration, for example, the zero point may be a position that minimizes the distance between the one or more contacts.

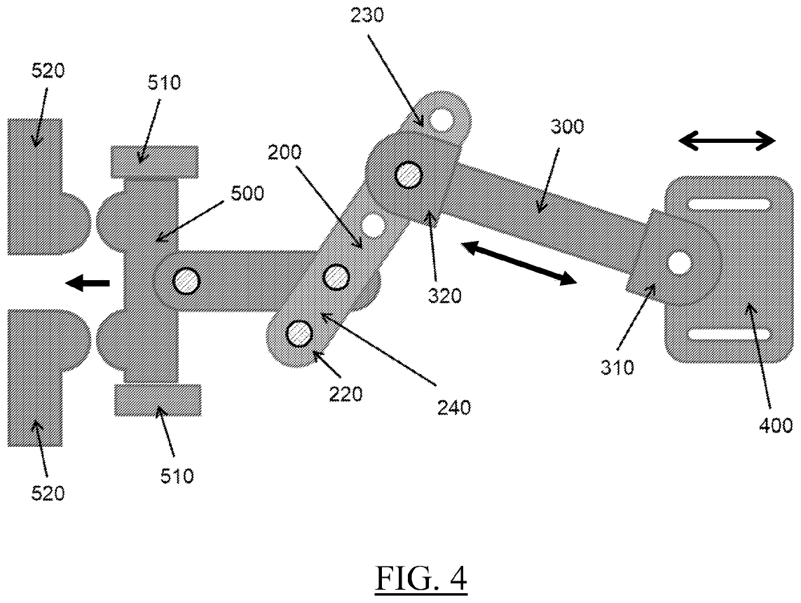

FIG. 4 is an illustration of an alternate arrangement of a second configuration of an exemplary piezoelectric switch in accordance with an exemplary embodiment of the present disclosure. In some embodiments, the alternate arrangement can include the pivot 220 being disposed on an end of the mechanical lever 200, as shown in FIG. 4. The design advantages of placing the pivot 220 on an end of the mechanical lever 200 can include reducing the physical footprint of the piezoelectric switch 100, which can be ideal for specific applications, and placing the piezoelectric switch in a normally closed configuration, in contrast to the configurations shown in FIGS. 2-3. As mentioned previously, various gains for the piezoelectric switch 100 may be realized by increasing or decreasing the mechanical gain of the mechanical lever 200. In the alternate arrangement shown in FIG. 4, the mechanical gain may be increased by coupling the first end of the piezoelectric actuator 310 to the one or more holes 210 of the mechanical lever 200 proximal to the pivot 220. Conversely, the mechanical gain may be decreased by coupling the first end of the piezoelectric actuator 310 to the one or more holes 210 on the mechanical lever 200 distal to the pivot 220.

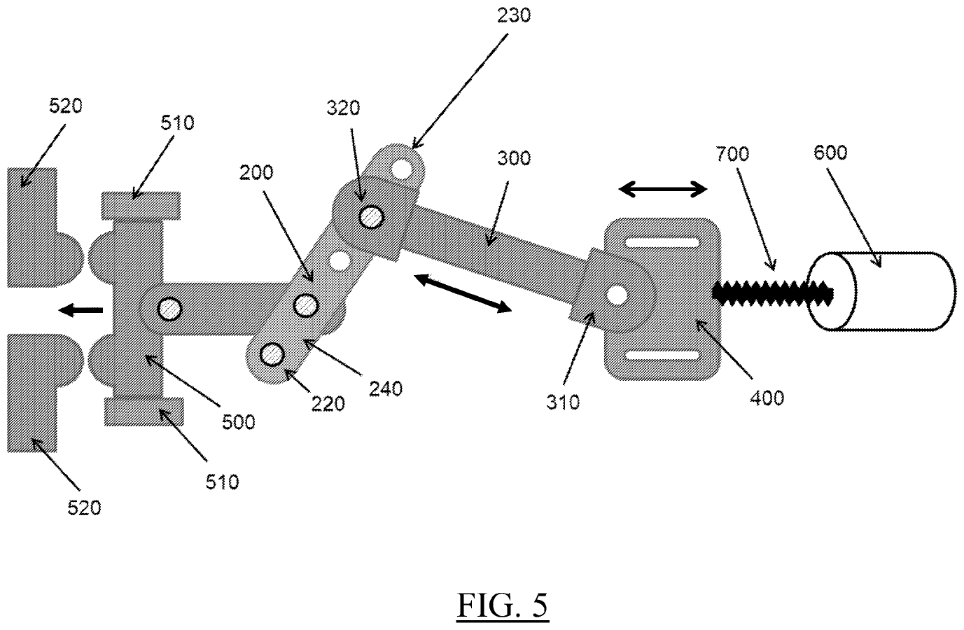

FIG. 5 is an illustration of an exemplary piezoelectric switch with a stepper motor and lead ball screw. Similar to FIG. 4, the piezoelectric switch 100, as shown in FIG. 5, can include the pivot 220 disposed on an end of the mechanical lever 200. In some embodiments, the piezoelectric switch 100 can also include a stepper motor 600 coupled to the counter block 400 via a lead ball screw 700. One of the design advantages of utilizing stepper motor 600 and lead ball screw 700 in conjunction with the counter block 400 is that it can enable adjustment of the counter block 400 to increase the contact force between the one or more contacts when the contacts are closed, which may not allow a user to access the fasten bolts to adjust the counter block 400 manually as discussed previously. Additionally, utilization of the stepper motor 600 and lead ball screw 700 with the counter block 400 allows a practitioner to compensate for factors that can impact the piezoelectric switch 100 during operation without opening the vacuum enclosure housing the piezoelectric switch 100. Factors that can impact the piezoelectric switch 100 wherein adjustments to the counter block 400 may be necessary can include but not be limited to temperature, pressure, mechanical wear, external forces and the like. In some embodiments, sensors and a closed loop control scheme may be implemented which can allow for monitoring environmental conditions and automatic compensation through adjusting the position of the counter block 400 with the stepper motor 600 and lead ball screw 700, which can be advantageous when manual adjustment of the counter block 400 may not be possible.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

1. A system comprising:
a mechanical lever comprising:
a first end comprising a pivot and holes disposed proximal to the pivot and spaced one from another, the first end configured to:
be coupled to an actuator via a couplable hole selected from the holes; and
provide a variable mechanical gain dependent upon the location of the couplable hole relative to the pivot; and
a second end configured to be coupled to at least a first moveable contact of one or more contacts.

2. The system of claim 1 further comprising:
one or more contacts; and
an actuator comprising:
a first end; and
a second end coupled to the couplable hole of the mechanical lever;
wherein a first moveable contact of the one or more contacts is coupled to the second end of the mechanical lever; and
wherein actuation of the actuator causes a displacement of the first moveable contact relative to a second contact of the one or more contacts.

3. The system of claim 2, wherein the second contact is a stationary contact.

4. The system of claim 2, wherein the second contact is a movable contact.

5. The system of claim 3, wherein the first movable contact is configured to be coupled to a first contact guide; and
wherein the first contact guide is configured to be disposed a variable distance from the second contact.

6. A system for an electromechanical transfer or disconnect switch comprising:
a first contact;
a second contact displaced from the first contact by a variable distance;
a mechanical lever coupled to the first contact;
an actuator coupled to the mechanical lever; and
a counter block;
wherein:
a first end of the mechanical lever comprises a pivot and holes spaced one from another;
a second end of the mechanical lever is coupled to the first contact;
a first end of the actuator is coupled to the counter block;
a second end of the actuator is coupled to the mechanical lever via a couplable hole selected from the holes of the first end of the mechanical lever;
the mechanical lever is configured to provide a variable mechanical gain dependent upon the location of the couplable hole relative to the pivot;
actuation of the actuator causes a displacement of the first contact relative to the second contact; and
the counter block is configured to adjust the variable distance between the first and second contacts.

7. The system of claim 6, wherein the actuator is a piezoelectric or magnetostrictive actuator.

8. The system of claim 7, wherein the piezoelectric actuator is configured to bias between an extended state and a retracted state.

9. The system of claim 8, wherein the piezoelectric actuator is further configured to bias between the extended state and the retracted state upon reception of an activation signal.

10. The system of claim 9, wherein the piezoelectric actuator is configured to, upon receiving the activation signal, bias to the extended state and is configured to displace the second end of the mechanical lever thus reducing the variable distance between the first and second contacts.

11. The system of claim 9, wherein the piezoelectric actuator is configured to, upon receiving the activation signal, bias to the retracted state and is configured to displace the second end of the mechanical lever thus increasing the variable distance between the first and second contacts.

12. (canceled)

13. The system of claim 6, wherein the variable mechanical gain of the mechanical lever is greater the more proximal the couplable hole is to the pivot.

14. The system of claim 6, wherein the variable mechanical gain of the mechanical lever is less the more distal the couplable hole is to the pivot.

15. The system of claim 6 further comprising:
a stepper motor configured to displace the counter block and therein adjust the variable distance between the first and second contacts.

16. The system of claim 15, wherein the stepper motor is further configured to be coupled to the counter block via a lead ball screw.

17.-18. (canceled)

19. An electromechanical transfer or disconnect switch comprising:
the system of claim 2;
wherein the second contact is selected from the group consisting of a stationary contact and a movable contact.

20. (canceled)

21. The switch of claim 19, wherein the first movable contact is coupled to a contact guide configured to be disposed a variable distance from the second contact being a stationary contact.

22. The switch of claim 21 further comprising:
a counter block coupled to the first end of the actuator; and
a stepper motor configured to displace the counter block;
wherein the counter block is configured to adjust the variable distance between the first and second contacts.

23. (canceled)

24. The switch of claim 21, wherein the actuator is configured to bias between an extended state and a retracted state;
wherein biasing to the extended state displaces the second end of the mechanical lever and reduces the variable distance between the first and second contacts; and
wherein biasing to the retracted state displaces the second end of the mechanical lever and increases the variable distance between the first and second contacts.

25.-30. (canceled)

31. The switch of claim 22, wherein the stepper motor is further configured to be coupled to the counter block via a lead ball screw.

32. The switch of claim 19, wherein the variable mechanical gain of the mechanical lever is:
greater the more proximal the couplable hole is to the pivot; and
less the more distal the couplable hole is to the pivot.
